(19) United States
(12) Patent Application Publication
(10) Pub. No.: US 2026/0133485 A1
(43) Pub. Date: May 14, 2026

(54) METHOD FOR MANUFACTURING SEMICONDUCTOR SUBSTRATE AND UNDERLAYER FILM-FORMING COMPOSITION

(71) Applicant: JSR CORPORATION, Tokyo (JP)

(72) Inventors: Ryuichi SERIZAWA, Tokyo (JP); Shuhei YAMADA, Tokyo (JP); Yuki OZAKI, Tokyo (JP); Hironori KIMATA, Tokyo (JP)

(73) Assignee: JSR CORPORATION, Tokyo (JP)

(21) Appl. No.: 19/443,419

(22) Filed: Jan. 8, 2026

Related U.S. Application Data
(63) Continuation-in-part of application No. PCT/JP2024/024583, filed on Jul. 8, 2024.

(30) Foreign Application Priority Data
Jul. 12, 2023 (JP) 2023-114155

(51) Int. Cl. G03F 7/004; G03F 7/00; G03F 7/11; G03F 7/16; H10P 76/20; H10P 76/40

(52) U.S. Cl. CPC G03F 7/0042; G03F 7/11; G03F 7/167; G03F 7/70033; H10P 76/2041; H10P 76/405; H10P 76/4085

(57) ABSTRACT

A method for manufacturing a semiconductor substrate includes: applying an underlayer film-forming composition directly or indirectly to a substrate to form an underlayer film; forming a metal-containing resist film from a metal-containing resist forming material on the underlayer film; exposing the metal-containing resist film to extreme ultraviolet rays; and developing the exposed metal-containing resist film. The underlayer film-forming composition includes: a metal compound including at least a metal atom and an organic acid; and a solvent.

### CROSS-REFERENCE TO RELATED APPLICATIONS

The present application is a continuation-in-part application of International Patent Application No. PCT/JP2024/024583 filed Jul. 8, 2024, which claims priority to Japanese Patent Application No. 2023-114155 filed Jul. 12, 2023. The contents of these applications are incorporated herein by reference in their entirety.

### BACKGROUND OF THE DISCLOSURE

### Technical Field

The present disclosure relates to a method for manufacturing a semiconductor substrate and an underlayer film-forming composition.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2022/260154).

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Accordingly, a metal-containing resist film is being used instead of the organic resist film.

Underlayer films for a metal-containing resist are required to have pattern rectangularity of securing rectangularity of a resist pattern by suppressing trailing of the pattern at the bottom of a resist film and development residues.

### SUMMARY

According to an aspect of the present disclosure, a method for manufacturing a semiconductor substrate includes: applying an underlayer film-forming composition (hereinafter, also referred to as “a first underlayer film-forming composition for a metal-containing resist”) directly or indirectly to a substrate to form an underlayer film (herein after also referred to as “an underlayer film for a metal-containing resist”; forming a metal-containing resist film from a metal-containing resist forming material (hereinafter, also referred to as “a second material for forming a metal-containing resist”) on the underlayer film; exposing the metal-containing resist film to extreme ultraviolet rays; and developing the exposed metal-containing resist film. The underlayer film-forming composition includes: a metal compound including at least a metal atom and an organic acid; and a solvent.

According to another aspect of the present disclosure, an underlayer film-forming composition includes: a metal compound including at least a metal atom and an organic acid; and a solvent.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

The present disclosure relates, in one embodiment, to a method for manufacturing a semiconductor substrate, the method including:
applying a first underlayer film-forming composition for a metal-containing resist directly or indirectly to a substrate;
forming a metal-containing resist film from a second material for forming a metal-containing resist on an underlayer film for a metal-containing resist formed by applying the first underlayer film-forming composition for a metal-containing resist;
exposing the metal-containing resist film to extreme ultraviolet rays; and
developing the exposed metal-containing resist film,
in which the first underlayer film-forming composition for a metal-containing resist includes a metal compound containing at least a metal atom and an organic acid (hereinafter also referred to as “compound [A]”), and a solvent (hereinafter also referred to as “solvent [B]”).

The present disclosure relates, in another embodiment, to a first underlayer film-forming composition for a metal-containing resist, the composition including:
a metal compound containing at least a metal atom and an organic acid; and
a solvent.

In the method for manufacturing a semiconductor substrate, the first underlayer film-forming composition for a metal-containing resist includes a metal compound containing at least a metal atom and an organic acid. Thanks to this, an underlayer film for a metal-containing resist capable of imparting excellent pattern rectangularity to a metal-containing resist film is formed, and that makes it possible to efficiently manufacture a high-quality semiconductor substrate. According to the first underlayer film-forming composition for a metal-containing resist, it is possible to efficiently form an underlayer film for a metal-containing resist film capable of imparting excellent pattern rectangularity to a metal-containing resist film. Therefore, these can be suitably used for the manufacture of a semiconductor device, and the like.

Hereinafter, a method for manufacturing a semiconductor substrate and a first underlayer film-forming composition for a metal-containing resist according to embodiments of the present disclosure will be described in detail. Combinations of suitable modes in embodiments are also preferred.

### <<Method for Manufacturing Semiconductor Substrate>>

The method for manufacturing a semiconductor substrate according to the present embodiment includes: applying a first underlayer film-forming composition for a metal-containing resist directly or indirectly to a substrate (hereinafter also referred to as “application step”); forming a metal-containing resist film from a second material for forming a metal-containing resist on the underlayer film for a metal-containing resist formed by applying the first underlayer film-forming composition for a metal-containing resist (hereinafter also referred to as “metal-containing resist film forming step”); exposing the metal-containing resist film to extreme ultraviolet rays (hereinafter also referred to as “exposing step”); and developing the exposed metal-containing resist film (hereinafter also referred to as “developing step”).

The method for manufacturing a semiconductor substrate may further include, as necessary, forming an organic underlayer film directly or indirectly on the substrate (hereinafter also referred to as “organic underlayer film forming step”) before the application step.

Hereinafter, description will be made about the first underlayer film-forming composition for a metal-containing resist to be used in the method for manufacturing a semiconductor substrate; and a case including the organic underlayer film forming step to be conducted before the step of forming an underlayer film for a metal-containing resist, which is an optional step.

### <First Composition for Forming Underlayer Film for Metal-Containing Resist>

The composition contains a compound [A] and a solvent [B]. The composition may further contain other optional components as long as the effects of the present invention are not impaired.

### [Compound [A]]

The compound [A] is a compound formed from at least a metal atom and an organic acid. Examples of the metal atom constituting the compound [A] include metal atoms of Groups 3 to 16 of the periodic table (excluding silicon atom). The compound [A] may have one kind or two or more kinds of metal atom.

Examples of Group 3 metal atom include scandium, yttrium, lanthanum, and cerium;
examples of Group 4 metal atom include titanium, zirconium, and hafnium;
examples of Group 5 metal atom include vanadium, niobium, and tantalum;
examples of Group 6 metal atom include chromium, molybdenum, and tungsten;
examples of Group 7 metal atom include manganese and rhenium;
examples of Group 8 metal atom include iron, ruthenium, and osmium;
examples of Group 9 metal atom include cobalt, rhodium, and iridium;
examples of Group 10 metal atom include nickel, palladium, and platinum;
examples of Group 11 metal atom include copper, silver, and gold;
examples of Group 12 metal atom include zinc, cadmium, and mercury;
examples of Group 13 metal atom include aluminum, gallium, and indium;
examples of Group 14 metal atom include germanium, tin, and lead;
examples of Group 15 metal atom include antimony and bismuth; and
examples of Group 16 metal atom include tellurium.

As the metal atom constituting the compound [A], metal atoms of Group 3 to Group 16 are preferable, metal atoms of Group 4 to Group 14 are more preferable, metal atoms of Group 4, Group 5, and Group 14 are still more preferable, and metal atoms of Group 4 are particularly preferable. Specifically, titanium, zirconium, hafnium, tantalum, tungsten, tin, or a combination thereof is more preferable.

The compound [A] includes at least an organic acid (hereinafter also referred to as “organic acid [a]”) as a component other than the metal atom (this component is hereinafter also referred to as “compound [x]”). Examples of the compound [x] other than the organic acid [a] include a hydroxy acid ester, a β-diketone, an α,α-dicarboxylic acid ester, and an amine compound. Herein, the “organic acid” refers to any organic compound that exhibits acidity, and the “organic compound” refers to any compound having at least one carbon atom.

Examples of the organic acid [a] include carboxylic acids, sulfonic acids, sulfinic acids, organic phosphinic acids, organic phosphonic acids, phenols, enols, thiols, acid imides, oximes, and sulfonamides.

Examples of the carboxylic acids include monocarboxylic acids such as formic acid, acetic acid, propionic acid, butanoic acid (butyric acid), isobutyric acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid, and shikimic acid; dicarboxylic acids such as oxalic acid, malonic acid, maleic acid, methylmalonic acid, fumaric acid, adipic acid, sebacic acid, phthalic acid, and tartaric acid; and carboxylic acids having three or more carboxy groups such as citric acid.

Examples of the sulfonic acids include benzenesulfonic acid and p-toluenesulfonic acid.

Examples of the sulfinic acids include benzenesulfinic acid and p-toluenesulfinic acid.

Examples of the organic phosphinic acids include diethylphosphinic acid, methylphenylphosphinic acid, and diphenylphosphinic acid.

Examples of the organic phosphonic acids include methylphosphonic acid, ethylphosphonic acid, t-butylphosphonic acid, cyclohexylphosphonic acid, and phenylphosphonic acid.

Examples of the phenols include monohydric phenols such as phenol, cresol, 2,6-xylenol, and naphthol;
dihydric phenols such as catechol, resorcinol, hydroquinone, and 1,2-naphthalenediol; and
trihydric or higher phenols such as pyrogallol and 2,3,6-naphthalenetriol.

Examples of the enols include 2-hydroxy-3-methyl-2-butene and 3-hydroxy-4-methyl-3-hexene.

Examples of the thiols include mercaptoethanol and mercaptopropanol.

Examples of the acid imides include carboxylic acid imides such as maleimide and succinimide, and sulfonic acid imides such as di(trifluoromethanesulfonic acid) imide and di(pentafluoroethanesulfonic acid) imide.

Examples of the oximes include aldoximes such as benzaldoxime and salicylaldoxime, and ketoximes such as diethylketoxime, methylethylketoxime, and cyclohexanone oxime.

Examples of the sulfonamides include methylsulfonamide, ethylsulfonamide, benzenesulfonamide, and toluenesulfonamide.

As the organic acid [a], a carboxylic acid is preferable, a monocarboxylic acid is more preferable, a monocarboxylic acid having 3 to 8 carbon atoms is still more preferable, and propionic acid, butyric acid, isobutyric acid, methacrylic acid, or 2-ethylhexanoic acid is particularly preferable.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the amine compound include diethanolamine and triethanolamine.

As the compound [A], a metal compound composed of a metal atom of Group 4, 5 or 14 and a carboxylic acid is preferable, a metal compound composed of a metal atom of Group 4 or 14 and a monocarboxylic acid having 3 to 8 carbon atoms is preferable, and a metal compound composed of titanium, zirconium, hafnium, tantalum, tungsten or tin and propionic acid, butyric acid, isobutyric acid, methacrylic acid or 2-ethylhexanoic acid is more preferable. The form of containing the organic acid [a] in the compound [A] also includes an organic acid anion obtained by removing a hydrogen ion from the organic acid [a].

The compound [A] may include one or two or more of the metal compound.

The compound [A] may include one or two or more of the organic acid [a].

The lower limit of the content ratio of the compound [A] to all components contained in the composition is preferably 0.05% by mass, more preferably 0.1% by mass, and still more preferably 0.5% by mass. The upper limit of the content ratio is preferably 20% by mass, more preferably 10% by mass, and still more preferably 5% by mass.

### [Method for Synthesizing Compound [A]]

The compound [A] can be synthesized by, for example, a method of performing a hydrolysis-condensation reaction using a metal-containing compound (hereinafter also referred to as “metal-containing compound [b]”), a method of performing a ligand substitution reaction using a metal-containing compound [b], or the like. Herein, the “hydrolysis-condensation reaction” refers to a reaction in which the hydrolyzable group of the metal-containing compound [b] is hydrolyzed to be converted into —OH, and the resulting two —OH groups are dehydration-condensed to form —O—.

(Metal-Containing Compound [b])

The metal-containing compound [b] is a metal compound precursor (b1) having a hydrolyzable group, a hydrolysate of a metal compound precursor (b1) having a hydrolyzable group, a hydrolysis-condensate of a metal compound precursor (b1) having a hydrolyzable group, or a combination thereof. The metal compound precursor (b1) may be used singly or two or more thereof may be used in combination.

Examples of the hydrolyzable group include a halogen atom, an alkoxy group, and an acyloxy group.

Examples of the halogen atom include a fluorine atom, a chlorine atom, a bromine atom, and an iodine atom.

Examples of the alkoxy group include a methoxy group, an ethoxy group, a n-propoxy group, an isopropoxy group, and a n-butoxy group.

Examples of the acyloxy group include an acetoxy group, an ethylyloxy group, a propionyloxy group, a butyryloxy group, a t-butyryloxy group, a t-amylyloxy group, an n-hexanecarbonyloxy group, and an n-octanecarbonyloxy group.

As the hydrolyzable group, an alkoxy group and an acyloxy group are preferable, and an isopropoxy group and an acetoxy group are more preferable.

When the metal-containing compound [b] is a hydrolysis-condensate of a metal compound precursor (b1), the hydrolysis-condensate of the metal compound precursor (b1) may be a hydrolysis-condensate of the metal compound precursor (b1) having a hydrolyzable group and a compound containing a metalloid atom as long as the effect of the present invention is not impaired. That is, the hydrolysis-condensate of the metal compound precursor (b1) may contain a metalloid atom as long as the effect of the present invention is not impaired. Examples of the metalloid atom include silicon, boron, germanium, antimony, and tellurium. The content of the metalloid atom in the hydrolysis-condensate of the metal compound precursor (b1) is usually less than 50 atom % based on the total of the metal atom and the metalloid atom in the hydrolysis-condensate. The upper limit of the content of the metalloid atom is preferably 30 atom %, more preferably 10 atom % based on the total of the metal atom and the metalloid atom in the hydrolysis-condensate.

Examples of the metal compound precursor (b1) include a compound represented by formula (a) (hereinafter also referred to as “compound [m]”).

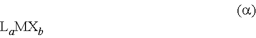

In the formula (a), M is a metal atom. L is a ligand. a is an integer of 0 to 4. When a is 2, a plurality of L's are the same or different. Y is a hydrolyzable group selected from among a halogen atom, an alkoxy group, and an acyloxy group. b is an integer of 0 to 6. The plurality of Y's may be the same or different. Note that a+b is 4 or more, and L is a ligand that does not correspond to Y.

Examples of the metal atom represented by M include metal atoms the same as those disclosed as examples of the metal atom constituting the compound [A].

Examples of the ligand represented by L include a monodentate ligand and a multidentate ligand.

Examples of the monodentate ligand include a hydroxo ligand, a carboxy ligand, an amide ligand, and ammonia.

Examples of the amide ligand include an unsubstituted amide ligand (NH₂), a methylamide ligand (NHMe), a dimethylamide ligand (NMe₂), a diethylamide ligand (NEt₂), and a dipropylamide ligand (NPr₂).

Examples of the multidentate ligand include hydroxy acid esters, β-diketones, β-ketoesters, β-dicarboxylic acid esters, hydrocarbons having a r bond, and diphosphines.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the β-dicarboxylic acid esters include malonic diesters, α-alkyl-substituted malonic diesters, α-cycloalkyl-substituted malonic diesters, and α-aryl-substituted malonic diesters.

Examples of the hydrocarbons having a n bond include
chain olefins such as ethylene and propylene;
cyclic olefins such as cyclopentene, cyclohexene, and norbornene;
chain dienes such as butadiene and isoprene;
cyclic dienes such as cyclopentadiene, methylcyclopentadiene, pentamethylcyclopentadiene, cyclohexadiene, and norbornadiene; and
aromatic hydrocarbons such as benzene, toluene, xylene, hexamethylbenzene, naphthalene, and indene.

Examples of the diphosphines include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, and 1,1′-bis(diphenylphosphino)ferrocene.

Examples of the halogen atom represented by Y include a fluorine atom, a chlorine atom, a bromine atom, and an iodine atom.

Examples of the alkoxy group represented by Y include a methoxy group, an ethoxy group, a propoxy group, and a butoxy group.

Examples of the acyloxy group represented by Y include an acetoxy group, an ethylyloxy group, a butyryloxy group, a t-butyryloxy group, a t-amylyloxy group, an n-hexanecarbonyloxy group, and an n-octanecarbonyloxy group.

As Y, an alkoxy group and an acyloxy group are preferable, and an isopropoxy group and an acetoxy group are more preferable.

As b, 3 and 4 are preferable, and 4 is more preferable.

As the metal-containing compound [b], metal alkoxides subjected to neither hydrolysis nor hydrolysis-condensation and metal acyloxides subjected to neither hydrolysis nor hydrolysis-condensation are preferable.

Examples of the metal-containing compound [b] include zirconium tetra-n-butoxide, zirconium tetra-n-propoxide, zirconium tetraisopropoxide, hafnium tetraethoxide, indium triisopropoxide, hafnium tetraisopropoxide, hafnium tetra-n-propoxide, hafnium tetra-n-butoxide, tantalum pentaethoxide, tantalum penta-n-butoxide, tungsten pentamethoxide, tungsten pentaethoxide, tungsten penta-n-butoxide, tungsten hexaethoxide, tungsten hexa-n-butoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxide stearate, bis(cyclopentadienyl)hafnium dichloride, bis(cyclopentadienyl)tungsten dichloride, diacetato[(S)-(−)-2,2′-bis(diphenylphosphino)-1,1′-binaphthyl]ruthenium, dichloro[ethylenebis(diphenylphosphine)]cobalt, titanium butoxide oligomer, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-isopropoxymono(acetylacetonato)titanium, triethoxymono(acetylacetonato)zirconium, tri-n-propoxymono(acetylacetonato)zirconium, tri-isopropoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tetrakis(dimethylamido)tin, tetrakis(ethylmethylamido)tin, tetrakis(diethylamido)tin, tin tetramethoxide, tin tetraethoxide, tin tetra-n-propoxide, tin tetraisopropoxide, tin tetra-n-butoxide, tin tetraisobutoxide, tin tetra-s-butoxide, tin tetra-t-butoxide, lanthanum oxide, and yttrium oxide.

Among them, metal alkoxides and metal acyloxides are preferable, metal alkoxides are more preferable, and alkoxides of titanium, zirconium, hafnium, tantalum, tungsten, and tin are still more preferable.

The lower limit of the amount of the organic acid used for the synthesis of the compound [A] is preferably 1 mol, more preferably 2 mol, per mole of the metal-containing compound [b]. On the other hand, the upper limit of the amount of the organic acid used is preferably 6 mol, more preferably 5 mol, per mole of the metal-containing compound [b].

In the synthesis reaction of the compound [A], in addition to the metal compound precursor (b1) and the organic acid [a], a compound capable of serving as a multidentate ligand represented by L in the compound of the formula (a), a compound capable of serving as a bridging ligand, or the like may be added. Examples of the compound capable of serving as a bridging ligand include compounds having a plurality of hydroxy groups, isocyanate groups, amino groups, ester groups, or amide groups.

Examples of the method of performing the hydrolysis-condensation reaction using the metal-containing compound [b] include a method of subjecting the metal-containing compound [b] to a hydrolysis-condensation reaction in a solvent containing water. In this case, another compound having a hydrolyzable group may be added, as necessary. The lower limit of the amount of water used in the hydrolysis-condensation reaction is preferably 0.2 times mol, more preferably 1 time mol, and still more preferably 3 times mol, in the number of moles, based on the hydrolyzable group of the metal-containing compound [b] and the like. The upper limit of the amount of water is preferably 20 times mol, more preferably 15 times mol, and still more preferably 10 times mol.

Examples of the method of performing the ligand substitution reaction using the metal-containing compound [b] include a method involving mixing the metal-containing compound [b] and the organic acid [a]. In this case, the metal-containing compound [b] and the organic acid [a] may be mixed in a solvent, or may be mixed without using a solvent. In the mixing, a base such as triethylamine may be added, as necessary. The addition amount of the base is, for example, 1 part by mass or more and 200 parts by mass or less based on 100 parts by mass of the total use amount of the metal-containing compound [b] and the organic acid [a].

The solvent to be used in the synthesis reaction of the compound [A](hereinafter also referred to as “solvent [d]”) is not particularly limited, and for example, the same solvents as those disclosed as examples of the solvent [B] described later can be used. Among them, alcohol-based solvents, ether-based solvents, ester-based solvents, and hydrocarbon-based solvents are preferable, alcohol-based solvents, ether-based solvents, and ester-based solvents are more preferable, monoalcohol-based solvents, polyhydric alcohol partial ether-based solvents, and polyhydric alcohol partial ether carboxylate-based solvents are still more preferable, and monoalcohol-based solvents having 1 to 4 carbon atoms, propylene glycol monoethyl ether, and propylene glycol monoethyl ether acetate are particularly preferable.

When the solvent [d] is used in the synthesis reaction of the compound [A], the solvent used may be removed after the reaction, but may be used as it is as the solvent [B] of the composition for forming a resist underlayer film without being removed after the reaction.

### [Solvent [B]]

The solvent [B] is not particularly limited as long as it is a solvent capable of dissolving or dispersing at least the compound [A], other optional components, and the like. The composition may contain one or two or more of the solvent [B].

Examples of the solvent [B] include organic solvents. Examples of the organic solvent include alcohol-based solvents, ketone-based solvents, ether-based solvents, ester-based solvents, nitrogen-containing solvents, and sulfur-containing solvents.

Examples of the alcohol-based solvents include monoalcohol-based solvents such as methanol, ethanol, n-propanol, isopropanol, and 1-butanol, and polyhydric alcohol-based solvents such as ethylene glycol, 1,2-propylene glycol, triethylene glycol, and tripropylene glycol.

Examples of the ketone-based solvents include chain ketone-based solvents such as methyl ethyl ketone, methyl isobutyl ketone, and 2-heptanone; and cyclic ketone-based solvents such as cyclohexanone.

Examples of the ether-based solvents include chain ether-based solvents such as n-butyl ether; polyhydric alcohol ether-based solvents such as cyclic ether-based solvents such as tetrahydrofuran and 1,4-dioxane; and polyhydric alcohol partial ether-based solvents such as propylene glycol monoethyl ether, tripropylene glycol monomethyl ether, and tetraethylene glycol monomethyl ether.

Examples of the ester-based solvents include carbonate-based solvents such as diethyl carbonate; acetic acid monoacetate ester-based solvents such as methyl acetate, ethyl acetate, and butyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the nitrogen-containing solvents include chain nitrogen-containing solvents such as N,N-dimethylacetamide, and cyclic nitrogen-containing solvents such as N-methylpyrrolidone.

Examples of the sulfur-containing solvent include chain sulfur-containing solvents such as dimethylsulfone and dimethylsulfoxide, and cyclic sulfur-containing solvents such as sulfolane.

Additional examples include aromatic hydrocarbon-based solvents such as toluene, xylene, and mesitylene.

As the solvent [B], an alcohol-based solvent, an ether-based solvent, an ester-based solvent, a ketone-based solvent, or a combination thereof is preferable, a monoalcohol-based solvent, a polyhydric alcohol partial ether-based solvent, an acetic acid monoester-based solvent, a polyhydric alcohol partial ether carboxylate-based solvent, a chain ketone-based solvent, or a combination thereof is more preferable, and 4-methyl-2-pentanol, propylene glycol monomethyl ether, butyl acetate, propylene glycol monomethyl ether acetate, 2-heptanone, or a combination thereof is still more preferable.

The lower limit of the content of the solvent [B] to the total amount of the compound [A] and the solvent [B] is preferably 50% by mass, more preferably 60% by mass, and still more preferably 70% by mass. The upper limit of the content is preferably 99.9% by mass, more preferably 99.5% by mass, and still more preferably 99% by mass. When the content of the solvent [B] is adjusted within the above range, the preparation of the composition can be facilitated, and the coatability can be improved.

### [Other Optional Components]

The composition may contain, for example, an acid generating agent, a macromolecular additive, a polymerization inhibitor, a surfactant, etc. as components other than those described above.

When the composition contains other optional components, the content of the other optional components in the composition can be appropriately determined according to the type, function, and so on of the other optional components to be used.

The acid generating agent is a compound that generates an acid by radiation irradiation and/or heating. The composition may contain one or two or more of the acid generating agent.

Examples of the acid generating agent include an onium salt compound and an N-sulfonyloxyimide compound.

When the composition contains a macromolecular additive, the composition can further enhance the coatability to a substrate and an organic underlayer film and the continuity of a film. The composition may contain one or two or more of the macromolecular additive.

Examples of the macromolecular additive include (poly)oxyalkylene-based macromolecular compounds, fluorine-containing macromolecular compounds, and non-fluorine-containing macromolecular compounds.

Examples of the (poly)oxyalkylene-based macromolecular compounds include: polyoxyalkylenes such as a (poly)oxyethylene-(poly)oxypropylene adduct; (poly)oxyalkyl ethers such as diethylene glycol heptyl ether, polyoxyethylene oleyl ether, polyoxypropylene butyl ether, polyoxyethylene polyoxypropylene-2-ethyl hexyl ether, and an adduct of oxyethylene-oxypropylene to a higher alcohol having 12 to 14 carbon atoms; (poly)oxyalkylene (alkyl) aryl ethers such as polyoxypropylene phenyl ether and polyoxyethylene nonyl phenyl ether; acetylene ethers obtained by addition polymerization of acetylene alcohol and an alkylene oxide, such as 2,4,7,9-tetramethyl-5-decyne-4,7-diol, 2,5-dimethyl-3-hexyne-2,5-diol, and 3-methyl-1-butyn-3-ol; (poly)oxyalkylene fatty acid esters such as diethylene glycol oleic acid ester, diethylene glycol lauric acid ester, and ethylene glycol distearic acid ester; (poly)oxyalkylene sorbitan fatty acid esters such as polyoxyethylene sorbitan monolauric acid ester and polyoxyethylene sorbitan trioleic acid ester; (poly)oxyalkylene alkyl (aryl) ether sulfuric acid ester salts such as polyoxypropylene methyl ether sodium sulfate and polyoxyethylene dodecyl phenol ether sodium sulfate; (poly)oxyalkylene alkyl phosphoric acid esters such as (poly)oxyethylene stearyl phosphoric acid ester; and (poly)oxyalkylene alkyl amines such as polyoxyethylene lauryl amine.

Examples of the fluorine-containing macromolecular compounds include compounds disclosed in JP-A-2011-89090. Examples of the fluorine-containing macromolecular compounds include compounds containing a repeating unit derived from a (meth)arylate compound having a fluorine atom and a repeating unit derived from a (meth)acrylate compound having two or more (preferably five or more) alkyleneoxy groups (preferably an ethyleneoxy group, a propyleneoxy group).

Examples of the non-fluorine-containing macromolecular compounds include compounds containing one kind or two or more kinds of repeating units derived from a (meth)acrylate monomer such as a linear or branched alkyl (meth)acrylate such as lauryl (meth)acrylate, 2-ethylhexyl (meth)acrylate, n-butyl (meth)acrylate, t-butyl (meth)acrylate, isooctyl (meth)acrylate, isostearyl (meth)acrylate, or isononyl (meth)acrylate, an alkoxyethyl (meth)acrylate such as methoxyethyl (meth)acrylate, an alkylene glycol di(meth)acrylate such as ethylene glycol di(meth)acrylate or 1,3-butylene glycol di(meth)acrylate, a hydroxyalkyl (meth)acrylate such as 2-hydroxyethyl (meth)acrylate, 2-hydroxypropyl (meth)acrylate, 2-hydroxybutyl (meth)acrylate, or 4-hydroxybutyl (meth)acrylate, dicyclopentenyloxyethyl (meth)acrylate, or nonylphenoxy polyethylene glycol (having a —(CH₂CH₂O)ₙ— structure, n=1 to 17) (meth)acrylate.

When the composition contains a polymerization inhibitor, the storage stability of the composition can be enhanced. The composition may contain one or two or more of the polymerization inhibitor.

Examples of the polymerization inhibitor include hydroquinone compounds such as 4-methoxyphenol and 2,5-di-tert-butylhydroquinone, and nitroso compounds such as N-nitrosophenylhydroxylamine and aluminum salts thereof.

When the composition contains a surfactant, the coatability to a substrate or an organic underlayer film and the continuity of a film can be further enhanced. The composition may contain one or two or more of the surfactant.

Examples of a commercially-available product of the surfactant include “Newcol 2320”, “Newcol 714-F”, “Newcol 723”, “Newcol 2307”, and “Newcol 2303” (which are all manufactured by NIPPON NYUKAZAI CO., LTD.), “Pionin D-1107-S”, “Pionin D-1007”, “Pionin D-1106-DIR”, “Newkalgen TG310”, “Pionin D-6105-W”, “Pionin D-6112”, and “Pionin D-6512” (which are all manufactured by TAKEMOTO OIL & FAT Co., Ltd.), “SURFYNOL 420” “SURFYNOL 440”, “SURFYNOL 465”, and “SURFYNOL 2502” (which are all manufactured by Air Products and Chemicals, Inc.), “MEGAFACE F171”, “MEGAFACE F172”, “MEGAFACE F173”, “MEGAFACE F176”, “MEGAFACE F177”, “MEGAFACE F141”, “MEGAFACE F142”, “MEGAFACE F143”, “MEGAFACE F144”, “MEGAFACE R30”, “MEGAFACE F437”, “MEGAFACE F475”, “MEGAFACE F479”, “MEGAFACE F482”, “MEGAFACE F562”, “MEGAFACE F563”, “MEGAFACE F780”, “MEGAFACE R-40”, “MEGAFACE DS-21”, “MEGAFACE RS-56”, “MEGAFACE RS-90”, and “MEGAFACE RS-72-K” (which are all manufactured by DIC Corporation), “Fluorad FC430” and “Fluorad FC431” (which are all manufactured by Sumitomo 3M Limited), “AsahiGuard AG710”, “Surflon S-382”, “Surflon SC-101”, “Surflon SC-102”, “Surflon SC-103”, “Surflon SC-104”, “Surflon SC-105”, and “Surflon SC-106 (which are all manufactured by AGC Inc.), and “FTX-218” and “NBX-15” (manufactured by NEOS Co., Ltd.).

### [Method for Preparing First Composition for Forming Underlayer Film for Metal-Containing Resist]

The first underlayer film-forming composition for a metal-containing resist can be prepared by mixing the compound [A], the solvent [B] and, as necessary, an optional component in a prescribed ratio and preferably filtering the resulting mixture through a membrane filter having a pore size of 0.5 μm or less, or the like.

### [Organic Underlayer Film Forming Step]

In this step, an organic underlayer film is formed directly or indirectly on the substrate before the application step. This step is an arbitrary step. Through this step, an organic underlayer film is formed directly or indirectly on the substrate.

The organic underlayer film can be formed by applying a composition for forming an organic underlayer film. The method of forming the organic underlayer film by applying the composition for forming an organic underlayer film may be, for example, a method in which a coating film formed by directly or indirectly applying the composition for forming an organic underlayer film to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is indirectly formed on a substrate include a case where an organic underlayer film is formed on a low dielectric insulating film formed on a substrate.

### [Application Step]

In this step, the first underlayer film-forming composition for a metal-containing resist is applied directly or indirectly to the substrate. By this step, a coating film of the composition is formed directly or indirectly on the substrate, and the coating film is usually cured by heating to form an underlayer film for a metal-containing resist as a resist underlayer film.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method for applying the underlayer film-forming composition for a metal-containing resist is not particularly limited, and examples thereof include a spin coating method.

Examples of the case where the first underlayer film-forming composition for a metal-containing resist is applied indirectly to the substrate include a case where the first underlayer film-forming composition for a metal-containing resist is applied to another film formed on the substrate. Other films formed on the substrate include, for example, an organic underlayer film which is formed by the organic underlayer film forming step described above, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the first underlayer film-forming composition for a metal-containing resist contains an acid generator, and the acid generator is a radiation-sensitive acid generator, the formation of the underlayer film for a metal-containing resist can be accelerated by combining heating and exposure. Radiation used for exposure includes, for example, the same radiation as exemplified in the exposing step described later.

The lower limit of the average thickness of the underlayer film for a metal-containing resist formed by this step is preferably 2 nm, more preferably 5 nm, and still more preferably 10 nm. The upper limit of the average thickness is preferably 40 nm, more preferably 30 nm, and still more preferably 20 nm. The method for measuring the average thickness of the underlayer film for a metal-containing resist is described in Examples.

### [Metal-Containing Resist Film Forming Step]

In this step, a metal-containing resist film is formed from a second material for forming a metal-containing resist on the underlayer film for a metal-containing resist formed by the step of applying a first underlayer film-forming composition for a metal-containing resist. The metal-containing resist film may be either a coating film or a deposited film, but is preferably a coating film.

### <Second Material for Forming a Metal-Containing Resist for Forming Coating Film>

The second material for forming a metal-containing resist for forming a coating film includes a metal-containing compound (A) and a solvent (hereinafter also referred to as “solvent (F)”), and a content ratio of the metal-containing compound (A) to components other than the solvent (F) in the material for forming a metal-containing resist is 50% by mass or more. The second material for forming a metal-containing resist may further contain other components.

### (Metal-Containing Compound (A))

The metal-containing compound (A) is a compound containing a metal atom. The metal-containing compound (A) may be used singly or in combination of two or more kinds thereof. In addition, the metal atom constituting the metal-containing compound (A) may be used singly or in combination of two or more kinds thereof. Here, the “metal atom” is a concept including a metalloid, that is, boron, silicon, germanium, arsenic, antimony, and tellurium.

The metal atom constituting the metal-containing compound (A) is not particularly limited. Examples thereof include metal atoms of Groups 3 to 16. Specific examples of the metal atom include a metal atom of Group 4 such as titanium, zirconium, and hafnium; a metal atom of Group 5 such as tantalum; a metal atom of Group 6 such as chromium and tungsten; a metal atom of Group 8 such as iron and ruthenium; a metal atom of Group 9 such as cobalt; a metal atom of Group 10 such as nickel; a metal atom of Group 11 such as copper; a metal atom of Group 12 such as zinc, cadmium, and mercury; a metal atom of Group 13 such as boron, aluminum, gallium, indium, and thallium; a metal atom of Group 14 such as germanium, tin, and lead; a metal atom of Group 15 such as antimony and bismuth; and a metal atom of Group 16 such as tellurium.

The metal atom constituting the metal-containing compound (A) preferably includes a first metal atom belonging to Group 4, Group 12, or Group 14 and belonging to Period 4, Period 5, or Period 6 in the periodic table. That is, the metal atom preferably contains at least one of titanium, zirconium, hafnium, zinc, cadmium, mercury, germanium, tin, and lead. As described above, the metal-containing compound (A) contains the first metal atom to further promote the release of secondary electrons in the exposed portion of the resist film and the change in solubility of the metal-containing compound (A) in a developer due to the secondary electrons and the like. As a result, the pattern rectangularity can be improved. The first metal atom is preferably tin or zirconium.

The metal-containing compound (A) preferably further has an atom other than the metal atom. Examples of the other atom include a carbon atom, a hydrogen atom, an oxygen atom, a nitrogen atom, a phosphorus atom, a sulfur atom, and a halogen atom. Among these atoms, a carbon atom, a hydrogen atom, and an oxygen atom are preferable. The other atom in the metal-containing compound (A) can be used singly or in combination of two or more kinds thereof.

In the second material for forming a metal-containing resist, the lower limit of the content of the metal-containing compound (A) in terms of solid components is preferably 70% by mass, more preferably 90% by mass, and still more preferably 95% by mass. The content may be 100% by mass. Here, the solid components in the second material for forming a metal-containing resist refer to components other than the solvent (F) described later.

### (Synthesis Method of Metal-Containing Compound (A))

The metal-containing compound (A) can be obtained, for example, by a method of performing a hydrolysis condensation reaction, a ligand exchange reaction, or the like on a metal compound having a metal atom and a hydrolyzable group, a hydrolysate of the metal compound, a hydrolysis condensation product of the metal compound, or a combination thereof. The metal compound can be used singly or in combination of two or more kinds thereof.

The metal-containing compound (A) is preferably derived from a metal compound having a metal atom and a hydrolyzable group and represented by formula (4) (hereinafter, also referred to as a “metal compound precursor (1)”). By using such a metal compound precursor (1), a stable metal-containing compound (A) can be obtained.

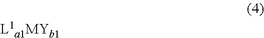

In the formula (4), M is a metal atom; L¹ is a ligand or a monovalent organic group having 1 to 20 carbon atoms; a1 is an integer of 0 to 6; when a1 is 2 or more, the plurality of L¹s may be the same or different from each other; Y is a monovalent hydrolyzable group; b1 is an integer of 2 to 6; the plurality of Ys may be the same or different from each other; and L¹ is a ligand or an organic group that is not Y.

As used herein, “organic group” means a group containing at least one carbon atom, and “carbon number” means the number of carbon atoms constituting the group.

The metal atom represented by M is preferably metal atoms of Group 14, and more preferably tin.

The hydrolyzable group represented by Y can be appropriately changed according to the metal atom represented by M. Examples thereof include a substituted or unsubstituted ethynyl group, a halogen atom, an alkoxy group, an acyloxy group, and a substituted or unsubstituted amino group.

As the substituent in the substituted or unsubstituted ethynyl group and the substituted or unsubstituted amino group represented by Y, a monovalent hydrocarbon group having 1 to 20 carbon atoms is preferable, a chain hydrocarbon group is more preferable, and an alkyl group is still more preferable.

Examples of the halogen atom represented by Y include a fluorine atom, a chlorine atom, a bromine atom, and an iodine atom. Among them, a chlorine atom is preferable.

Examples of the alkoxy group represented by Y include a methoxy group, an ethoxy group, a n-propoxy group, an i-propoxy group, and a n-butoxy group. Among them, an ethoxy group, an i-propoxy group, and a n-butoxy group are preferable.

Examples of the acyloxy group represented by Y include a formyl group, an acetoxy group, an ethyryloxy group, a propionyloxy group, a n-butyryloxy group, a t-butyryloxy group, a t-amyryloxy group, a n-hexanecarbonyloxy group, and a n-octanecarbonyloxy group. Among them, an acetoxy group is preferable.

Examples of the substituted or unsubstituted amino group represented by Y include an amino group, a methylamino group, a dimethylamino group, a diethylamino group, and a dipropylamino group. Among them, a dimethylamino group and a diethylamino group are preferable.

Hereinafter, preferred combinations of the metal atom represented by M and the hydrolyzable group represented by Y will be described. When the metal atom represented by M is tin, the hydrolyzable group represented by Y is preferably a substituted or unsubstituted ethynyl group, a halogen atom, an alkoxy group, an acyloxy group, and a substituted or unsubstituted amino group, and more preferably a halogen atom.

When the metal atom represented by M is germanium, the hydrolyzable group represented by Y is preferably a halogen atom, an alkoxy group, an acyloxy group, and a substituted or unsubstituted amino group. When the metal atom represented by M is hafnium, zirconium, and titanium, the hydrolyzable group represented by Y is preferably a halogen atom, an alkoxy group, and an acyloxy group.

Examples of the ligand represented by L¹ include a monodentate ligand and a multidentate ligand.

Examples of the monodentate ligand include a hydroxo ligand, a nitro ligand, and ammonia.

Examples of the multidentate ligand include a hydroxy acid ester, a β-diketone, a β-ketoester, a malonic acid diester in which a carbon atom at the α-position is optionally substituted, a hydrocarbon having a n bond, a ligand derived from these compounds, and a diphosphine.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, and 1,1′-bis(diphenylphosphino)ferrocene.

Examples of the monovalent organic group represented by L¹ include a monovalent hydrocarbon group having 1 to 20 carbon atoms, a group containing a divalent heteroatom-containing linking group between two carbon atoms of the foregoing hydrocarbon group, a group obtained by replacing some or all of the hydrogen atoms of the foregoing hydrocarbon group with a monovalent heteroatom-containing substituent, and a combination thereof.

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, or a combination thereof.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, a tert-butyl group, an n-pentyl group, an isopentyl group, and a neopentyl group; alkenyl groups such as an ethenyl group, a propenyl group, and a butenyl group; and alkynyl groups such as an ethynyl group, a propynyl group, and a butynyl group. In particular, alkyl groups having 1 to 8 carbon atoms are preferable.

Examples of the monovalent alicyclic hydrocarbon group having 3 to 20 carbon atoms include: cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include aryl groups such as a phenyl group, a tolyl group, a naphthyl group, and an anthracenyl group, a pyrenyl group, a fluorenyl group, and a 9-methylidenefluorenyl group, and aralkyl groups such as a benzyl group and a phenethyl group.

Examples of the heteroatom that constitutes the divalent heteroatom-containing linking group or the monovalent heteroatom-containing substituent include an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent heteroatom-containing linking group include —CO—, —CS—, —NH—, —O—, —S—, and groups obtained by combining them.

Examples of the monovalent heteroatom-containing substituent include a hydroxy group, a sulfanyl group, a cyano group, a nitro group, and a halogen atom.

Examples of the monovalent organic group represented by L¹ include groups similar to the groups exemplified as the monovalent organic group having 1 to 20 carbon atoms represented by Y in the formula (1-1) and the formula (1-2). The lower limit of the carbon number in the monovalent organic group represented by L¹ is preferably 2, and more preferably 3. On the other hand, the upper limit of the carbon number is preferably 10, and more preferably 5. The monovalent organic group represented by L¹ is preferably a substituted or unsubstituted hydrocarbon group, more preferably a substituted or unsubstituted chain hydrocarbon group or a substituted or unsubstituted aromatic hydrocarbon group, still more preferably a substituted or unsubstituted alkyl group or a substituted or unsubstituted aralkyl group, and particularly preferably an isopropyl group or a benzyl group.

a1 is preferably 1 or 2, and more preferably 1.

b1 is preferably an integer of 2 to 4. By setting b1 to the above numerical value, the content ratio of the metal atom in the metal-containing compound (A) can be increased, and the generation of secondary electrons by the metal-containing compound (A) can be more effectively promoted. As a result, the pattern rectangularity can be improved.

As the metal compound precursor (1), a metal halide compound is preferable, and isopropyltin trichloride or benzyltin trichloride is more preferable.

Examples of the method for performing a hydrolysis condensation reaction on the metal compound precursor (1) include a method in which the metal compound precursor (1) is stirred in water or a solvent containing water in the presence of a base such as tetramethylammonium hydroxide, which is used as necessary. In this case, another compound having a hydrolyzable group may be added, as necessary. The lower limit of the amount of water used in the hydrolysis condensation reaction is preferably 0.2 times mol, more preferably 1 time mol, and still more preferably 3 times mol, in the number of moles, based on the hydrolyzable group of the metal compound precursor (1) and the like. By setting the amount of water in the hydrolysis condensation reaction within the above range, the metal-containing compound (A) can be efficiently obtained.

In the synthesis reaction of the metal-containing compound (A), in addition to the metal compound precursor (1), a compound capable of serving as a multidentate ligand represented by L¹ in the compound of the formula (4), a compound capable of serving as a bridging ligand, or the like may be added. Examples of the compound capable of serving as a bridging ligand include compounds having two or more groups capable of serving as a ligand, such as a hydroxy group, an isocyanate group, an amino group, an ester group, and an amide group.

In the synthesis reaction of the metal-containing compound (A), the lower limit of the temperature is preferably 0° C., and more preferably 10° C. The upper limit of the temperature is preferably 150° C., more preferably 100° C., and still more preferably 50° C.

In the synthesis reaction of the metal-containing compound (A), the lower limit of the time is preferably 1 minute, more preferably 10 minutes, and still more preferably 1 hour. The upper limit of the time is preferably 100 hours, more preferably 50 hours, still more preferably 24 hours, and particularly preferably 4 hours.

### (Solvent (F))

The solvent (F) is preferably an organic solvent. Specific examples of the organic solvent include organic solvents similar to those exemplified as the solvent [B] in the first underlayer film-forming composition for a metal-containing resist described above.

As the solvent (F), an ether-based solvent is preferable, and propylene glycol monoethyl ether is more preferable.

### (Other Optional Components)

The second material for forming metal-containing resist may contain other optional components such as a compound capable of serving as a ligand, and a surfactant, in addition to the metal-containing compound (A) and the solvent (F).

### (Compound Capable of Serving as Ligand)

Examples of the compound capable of serving as a ligand include compounds capable of serving as a multidentate ligand or a bridging ligand, and specifically include the same compounds as the compounds capable of serving as a multidentate ligand or a bridging ligand exemplified in the synthesis method of the metal-containing compound (A).

### (Surfactant)

The surfactant is a component that exhibits an action of improving coatability, striation, and the like. Examples of the surfactant include nonionic surfactants, including polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of the product name thereof include KP341 (manufactured by Shin-Etsu Chemical Co., Ltd.), POLYFLOW No. 75, POLYFLOW No. 95 (both manufactured by Kyoeisha Chemical Co., Ltd.), EFTOP EF301, EFTOP EF303, EFTOP EF352 (all manufactured by Tohkem Products Corporation), MEGAFACE F171, MEGAFACE F173 (both manufactured by DIC), Fluorad FC430, Fluorad FC431 (both manufactured by Sumitomo 3M Limited), ASAHIGUARD AG710, SURFLON S-382, SURFLON SC-101, SURFLON SC-102, SURFLON SC-103, SURFLON SC-104, SURFLON SC-105, SURFLON SC-106 (all manufactured by Asahi Glass Co., Ltd.)

### (Method for Preparing Second Material for Forming Metal-Containing Resist)

The second material for forming a metal-containing resist can be prepared, for example, by mixing the metal-containing compound (A), the solvent (F) and, as necessary, other optional components in a prescribed ratio, and preferably filtering the obtained mixture through a membrane filter having a pore size of 0.4 μm or less. The content ratio of the metal-containing compound (A) to components other than the solvent (F) in the second material for forming a metal-containing resist is preferably 50% by mass or more. The lower limit of the content ratio of the metal-containing compound (A) is more preferably 60% by mass, and still more preferably 70% by mass. On the other hand, the upper limit of the content ratio is preferably 100% by mass, but may be 98% by mass, or may be 95% by mass.

<Method for Forming Coating Film from Second Material for Forming Metal-Containing Resist for Forming Coating Film>

The method for applying the second material for forming a metal-containing resist for forming a coating film is not particularly limited, and examples thereof include a spin coating method.

To explain this step in more detail, for example, after applying a second material for forming a metal-containing resist such that the formed metal-containing resist film has a prescribed thickness, pre-baking (hereinafter also referred to as “PB”) is performed to volatilize the solvent in the coating film to form a resist film.

The PB temperature and the PB time may be appropriately determined according to the type and the like of the second material for forming a metal-containing resist to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

### <Second Material for Forming a Metal-Containing Resist for Forming Deposited Film>

The second material for forming a metal-containing resist for forming a deposited film contains a metal-containing compound (B). The metal-containing resist film can be formed by depositing the metal-containing compound (B). The deposition is preferably conducted by chemical vapor deposition (CVD) or atomic layer deposition (ALD). The deposition may be conducted by plasma-enhanced (PE) CVD or plasma-enhanced (PE) ALD.

The metal atom contained in the metal-containing resist film is at least one selected from the group consisting of Sn and Hf.

Examples of the metal-containing compound (B) include a metal compound represented by the following formula (1).

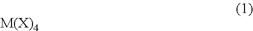

In the formula (1), M is Sn or Hf. Xs are each independently a halogen atom or an alkyl group.

Examples of the metal-containing compound (B) include Sn(CH₃)₄, Sn(Br)₄, and HfCl₄. As to the metal-containing compound (B), two or more kinds thereof may be used in combination.

Examples of the process conditions suitable for the deposition of Sn(CH₃)₄ on the underlayer film for a metal-containing resist include a deposition temperature between about −54° C. and 30° C. (e.g., about 20° C.) and a reactor pressure of 20 Torr or less (e.g., a pressure maintained at about 1 Torr at 20° C.). The deposition rate can be controlled by maintaining the flow rate of Sn(CH₃)₄ between about 100 sccm and 1000 sccm.

Examples of the process conditions suitable for the deposition of HfCl₄ on the underlayer film for a metal-containing resist include a deposition temperature between about 0° C. and 300° C. (e.g., about 100° C.) and a reactor pressure of 10 Torr or less (e.g., a pressure maintained between 0.1 and 1 Torr at 100° C.). The deposition rate can be controlled by maintaining the flow rate of HfCl₄ between about 10 sccm and 100 sccm.

The film of Sn(Br)₄ can be turned into a film of SnX₄ through a reaction of the following formula with a reactant X₂ (for example, when X is Cl, I, or H).

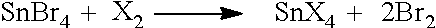

The film of HfCl₄ can be turned into a film of HfX₄ through a reaction of the following formula with a reactant X₂ (for example, when X is Br, I, or H).

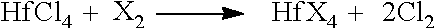

The lower limit of the average thickness of the metal-containing resist film to be formed is preferably 0.1 nm, more preferably 0.5 nm, and still more preferably 1 nm. The upper limit of the average thickness is preferably 50 nm, more preferably 20 nm, still more preferably 10 nm, and particularly preferably 5 nm. The average thickness is measured as described in Examples.

### [Exposing Step]

In this step, the metal-containing resist film is exposed to extreme ultraviolet rays (having a wavelength of 13.5 nm or the like, also referred to as “EUV”). This step causes a difference in properties between an exposed portion and an unexposed portion on the metal-containing resist film. In addition, exposure conditions can be appropriately determined depending on the type and the like of the second material for forming a metal-containing resist to be used.

When the metal-containing resist film is a coating film, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

When the metal-containing resist film is a deposited film, for example, EUV decomposes a metal-containing compound (B) (including SnX₄ or HfX₄) in an exposed portion of the metal-containing resist film. For example, when the metal-containing compound (B) is Sn(Br)₄, the decomposition reaction of the metal-containing compound (B) proceeds as follows.

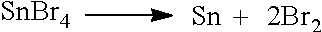

EUV directly decomposes SnBr₄ into Sn and bromine gas (Br₂)

When the metal-containing compound (B) is Sn(CH₃)₄, the decomposition reaction of the metal-containing compound (B) by EUV proceeds as in the following formula.

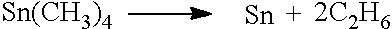

When the metal-containing compound (B) is HfCl₄, the decomposition reaction of the metal-containing compound (B) by EUV proceeds as in the following formula.

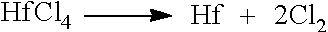

### [Developing Step]

In this step, the exposed metal-containing resist film is developed. The development may be dissolution in a developer or volatilization by heating or decompression. Thereby, a metal-containing resist pattern can be formed.

The development using a developer can be suitably applied to a coating film, and may be either alkaline development or organic solvent development. In the case of alkaline development, examples of the developer include basic aqueous solutions such as ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. In addition, in the case of organic solvent development, examples of the developer include the various organic solvents recited as examples of the solvent [B] of the first underlayer film-forming composition for a metal-containing resist described above.

When the development is conducted by volatilization, it can be suitably applied to a deposited film, and it is possible to form a pattern by volatilizing an unexposed portion of the exposed metal-containing resist film. The volatilization of the unexposed portion of the exposed metal-containing resist film can be performed by decompression, heating, or a combination thereof.

For example, in the case of a metal-containing resist film formed by deposition of Sn(CH₃)₄, since the exposed portion is turned into Sn, it is possible to develop the metal-containing resist film and form a pattern by volatilizing Sn(CH₃)₄ in the unexposed portion.

In this step, washing and/or drying may be performed after the development. In addition, etching may be performed using the metal-containing resist pattern as a mask. Examples of a method for etching include dry etching and wet etching.

### <<First Composition for Forming Underlayer Film for Metal-Containing Resist>>

The first underlayer film-forming composition for a metal-containing resist includes a metal compound composed of at least a metal atom and an organic acid, and a solvent. As the composition, the first underlayer film-forming composition for a metal-containing resist to be used in the above-described method for manufacturing a semiconductor substrate can be suitably employed.

### EXAMPLES

Hereinafter, Examples are described. The following Examples merely illustrate typical Examples of the present disclosure, and the Examples should not be construed to narrow the scope of the present disclosure.

The concentration of the components other than the solvent in the mixture containing the compound [A] in the present example, the weight average molecular weight (Mw) of the hydrolysis-condensate in the mixture containing the compound [A], and the average thickness of the film were measured by the following methods.

[Concentration of Components Other than Solvent in Mixture Containing Compound [A]]

By firing 0.5 g of a mixture containing the compound [A] at 250° C. for 30 minutes, measuring a mass of the residue thus obtained, and dividing the mass of the residue by the mass of the solution containing the compound [A], the concentration (% by mass) of the components other than the solvent in the mixture containing the compound [A] was calculated.

### [Weight Average Molecular Weight (Mw)]

The weight average molecular weight was measured by gel permeation chromatography (detector: differential refractometer) with monodisperse polystyrene standards using GPC columns (“AWM-H”×2, “AW-H”×1, and “AW2500”×2) manufactured by Tosoh Corporation under the analysis conditions specified by flow rate: 0.3 mL/min, elution solvent: mixture of N,N-dimethylacetamide with LiBr (30 mM) and citric acid (30 mM), and column temperature: 40° C.

### [Average Thickness of Underlayer Film for Metal-Containing Resist]

The average thickness of a underlayer film for a metal-containing resist was determined as a value attained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and the average thickness was determined by calculating the average value of the film thicknesses.

### <Synthesis of Compound [A]>

The compound [m], the compound [x], the solvent [d], and the solvent [B] used for the synthesis of the compound [A] are listed below. In the following synthesis examples, unless otherwise specified, “parts by mass” means a value taken when the mass of the compound [m] used is 100 parts by mass. In addition, the “molar ratio” means a value taken when the amount of the compound [m] used is 1. The concentrations (% by mass) of components other than the solvent in the mixture containing the compound [A] are also shown in Table 1. In Table 1 below, “-” indicates that the corresponding component was not used.

The following compounds were used as the compound [m].
m-1: Tetra-n-propoxyzirconium(IV)
m-2: Tetra-n-butoxyzirconium(IV)
m-3: Tetra-n-propoxyhafnium(IV)
m-4: Tetraisopropoxytitanium(IV)
m-5: Pentaethoxytantalum(V)
m-6: Tetramethoxytin(IV)
m-7: Tetraethoxytin(IV)
m-8: Tetra-n-propoxytin(IV)
m-9: Tetraisopropoxytin(IV)
m-10: Tetra-n-butoxytin(IV)
m-11: Tetraisobutoxytin(IV)
m-12: Tetra-sec-butoxytin(IV)
m-13: Tetra-tert-butoxytin(IV)
m-14: Tetrakis(dimethylamido)tin(IV)
m-15: Tetrakis(methylethylamido)tin(IV)
m-16: Tetrakis(diethylamido)tin(IV)
m-17: Pentaethoxytungsten(V)

The following compounds were used as the compound [x].
x-1: Propionic acid
x-2: Butyric acid
x-3: Isobutyric acid
x-4: Methacrylic acid
x-5: 2-Ethylhexanoic acid
x-6: Acrylic acid

The following compounds were used as the solvent [d].
d-1: n-Propyl alcohol
d-2: Ethanol
d-3: 1-Butanol
d-4: Isopropanol
d-5: Methanol
d-6: Isobutanol
d-7: sec-Butanol
d-8: tert-Butanol
d-9: Tetrahydrofuran
d-10: Methyl ethyl ketone

The following compounds were used as the solvent [B].
B-1: Propylene glycol monomethyl ether acetate
B-2: Propylene glycol monomethyl ether
B-3: 4-Methyl-2-pentanol

### [Synthesis Example 1-1] (Synthesis of compound [A](A-1))

The compound (m-1) and the solvent (d-1) (40 parts by mass) were charged into a reaction vessel under a nitrogen atmosphere. In the reaction vessel, the compound (x-1) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. The precipitate obtained via the cooling was collected by filtration, washed with n-hexane (100 parts by mass), and then vacuum-dried, affording compound (A-1).

### [Synthesis Example 1-2] (Synthesis of compound [A](A-2))

The compound (m-1) and the solvent (d-1) (200 parts by mass) were charged into a reaction vessel under a nitrogen atmosphere. In the reaction vessel, the compound (x-2) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. After 900 parts by mass of the solvent (B-1) was added to the cooled reaction solution, the solvent (d-1), the alcohol generated via the reaction, and the excess solvent (B-1) were removed using an evaporator, affording a mixture containing compound (A-2). The concentration of the components other than the solvent in the mixture containing the compound [A](A-2) was 14% by mass.

### [Synthesis Example 1-10] (Synthesis of compound [A](A-10))

Compound [A](A-10) was obtained in the same manner as in Synthesis Example 1-1 except that the compound [m], the compound [x] and the solvent [d] of the type and use amount given in the following Table 1 were used.

### Synthesis Examples 1-3 to 1-9, 1-11 to 1-20, and 1-28

### Synthesis of Compounds [A](A-3) to (A-9), (A-11) to (A-20), and (A-28)

Mixtures containing compounds [A](A-3) to (A-9), (A-11) to (A-20), and (A-28) were obtained in the same manner as in Synthesis Example 1-2 except that the compound [m], the compound [x], the solvent [d], and the solvent [B] of the type and use amount given in the following Table 1 were used.

### [Synthesis Example 1-21] (Synthesis of compound [A](A-21))

The compound (m-14) and the solvent (d-9) (50 parts by mass) were charged into a reaction vessel under a nitrogen atmosphere. In the reaction vessel, the compound (x-1) (molar ratio: 4) was added dropwise over 30 minutes with stirring at 5° C. The reaction was then conducted at 70° C. for 2 hours. After the completion of the reaction, the inside of the reaction vessel was cooled to 30° C. or lower. After 700 parts by mass of the solvent (B-1) was added to the cooled reaction solution, the solvent (d-9), the amine generated via the reaction, and the excess solvent (B-1) were removed using an evaporator, affording a mixture containing compound (A-21). The concentration of the components other than the solvent in the mixture containing the compound [A](A-21) was 21% by mass.

### [Synthesis Examples 1-22 to 1-27] (Synthesis of compounds [A](A-22) to (A-27))

Mixtures containing compounds [A](A-22) to (A-27) were obtained in the same manner as in Synthesis Example 1-21 except that the compound [m], the compound [x], the solvent [d], and the solvent [B] of the type and use amount given in the following Table 1 were used.

TABLE 1

| | | | | | | | | Concentration of |
|---|---|---|---|---|---|---|---|---|
| | | | | | | | | components |
| | | | | | | | | other than |
| | | | | | | | | solvent |
| | | | | | | | | in mixture |
| | | Compound | | Compound | | Solvent | Solvent | containing |
| | Compound | [m] | | [x] | | [d] | [B] | compound [A] |
| | [A] | Type | mol % | Type | mol % | Type | Type | (% by mass) |
| Synthesis | A-1 | m-1 | 1 | x-1 | 5 | d-1 | — | 100 |
| Example | | | | | | | | |
| 1-1 | | | | | | | | |
| Synthesis | A-2 | m-1 | 1 | x-2 | 5 | d-1 | B-1 | 14 |
| Example | | | | | | | | |
| 1-2 | | | | | | | | |
| Synthesis | A-3 | m-1 | 1 | x-3 | 5 | d-1 | B-1 | 14 |
| Example | | | | | | | | |
| 1-3 | | | | | | | | |
| Synthesis | A-4 | m-1 | 1 | x-4 | 1 | d-1 | B-1 | 13 |
| Example | | | | | | | | |
| 1-4 | | | | | | | | |
| Synthesis | A-5 | m-1 | 1 | x-4 | 2 | d-1 | B-1 | 13 |
| Example | | | | | | | | |
| 1-5 | | | | | | | | |
| Synthesis | A-6 | m-1 | 1 | x-4 | 3 | d-1 | B-1 | 13 |
| Example | | | | | | | | |
| 1-6 | | | | | | | | |
| Synthesis | A-7 | m-1 | 1 | x-4 | 5 | d-1 | B-1 | 20 |
| Example | | | | | | | | |
| 1-7 | | | | | | | | |
| Synthesis | A-8 | m-1 | 1 | x-5 | 5 | d-1 | B-1 | 20 |
| Example | | | | | | | | |
| 1-8 | | | | | | | | |
| Synthesis | A-9 | m-2 | 1 | x-4 | 5 | d-3 | B-1 | 20 |
| Example | | | | | | | | |
| 1-9 | | | | | | | | |
| Synthesis | A-10 | m-3 | 1 | x-4 | 5 | d-1 | — | 100 |
| Example | | | | | | | | |
| 1-10 | | | | | | | | |
| Synthesis | A-11 | m-4 | 1 | x-3 | 5 | d-4 | B-1 | 13 |
| Example | | | | | | | | |
| 1-11 | | | | | | | | |
| Synthesis | A-12 | m-5 | 1 | x-3 | 6 | d-2 | B-1 | 13 |
| Example | | | | | | | | |
| 1-12 | | | | | | | | |
| Synthesis | A-13 | m-6 | 1 | X-1 | 5 | d-5 | B-2 | 20 |
| Example | | | | | | | | |
| 1-13 | | | | | | | | |
| Synthesis | A-14 | m-7 | 1 | x-1 | 5 | d-2 | B-2 | 20 |
| Example | | | | | | | | |
| 1-14 | | | | | | | | |
| Synthesis | A-15 | m-8 | 1 | x-1 | 5 | d-1 | B-2 | 20 |
| Example | | | | | | | | |
| 1-15 | | | | | | | | |
| Synthesis | A-16 | m-9 | 1 | x-2 | 5 | d-4 | B-2 | 20 |
| Example | | | | | | | | |
| 1-16 | | | | | | | | |
| Synthesis | A-17 | m-10 | 1 | x-3 | 5 | d-3 | B-2 | 20 |
| Example | | | | | | | | |
| 1-17 | | | | | | | | |
| Synthesis | A-18 | m-11 | 1 | x-3 | 5 | d-6 | B-2 | 20 |
| Example | | | | | | | | |
| 1-18 | | | | | | | | |
| Synthesis | A-19 | m-12 | 1 | x-4 | 5 | d-7 | B-2 | 20 |
| Example | | | | | | | | |
| 1-19 | | | | | | | | |
| Synthesis | A-20 | m-13 | 1 | x-5 | 5 | d-8 | B-2 | 20 |
| Example | | | | | | | | |
| 1-20 | | | | | | | | |
| Synthesis | A-21 | m-14 | 1 | X-1 | 4 | d-9 | B-1 | 21 |
| Example | | | | | | | | |
| 1-21 | | | | | | | | |
| Synthesis | A-22 | m-14 | 1 | x-1 | 4 | d-9 | B-3 | 21 |
| Example | | | | | | | | |
| 1-22 | | | | | | | | |
| Synthesis | A-23 | m-14 | 1 | x-4 | 4 | d-9 | B-3 | 21 |
| Example | | | | | | | | |
| 1-23 | | | | | | | | |
| Synthesis | A-24 | m-14 | 1 | x-4 | 4 | d-9 | B-2 | 20 |
| Example | | | | | | | | |
| 1-24 | | | | | | | | |
| Synthesis | A-25 | m-15 | 1 | x-1 | 4 | d-9 | B-2 | 21 |
| Example | | | | | | | | |
| 1-25 | | | | | | | | |
| Synthesis | A-26 | m-16 | 1 | x-6 | 4 | d-10 | B-3 | 20 |
| Example | | | | | | | | |
| 1-26 | | | | | | | | |
| Synthesis | A-27 | m-16 | 1 | x-6 | 2 | d-10 | B-3 | 20 |
| Example | | | | | | | | |
| 1-27 | | | | | | | | |
| Synthesis | A-28 | m-17 | 1 | x-3 | 6 | d-2 | B-2 | 20 |
| Example | | | | | | | | |
| 1-28 | | | | | | | | |

### <Preparation of First Underlayer Film-Forming Composition for a Metal-Containing Resist>

The compound [A], the solvent [B], and other optional components [F] used for the preparation of the first underlayer film-forming composition for a metal-containing resist (hereinafter also referred to as “composition”) are shown below.

The compounds (A-1) to (A-28) synthesized above were used as the compound [A].

In addition to (B-1) to (B-3) used for the synthesis of the compound [A], the following compounds were used as the solvent [B].
B-4: Cyclohexanone
B-5: Butyl acetate
B-6: 2-Heptanone

The following compounds were used as other optional components [F].
F-1: 4-Methoxyphenol
F-2 (Ortho ester): Trimethyl orthoformate
F-3 (Acid generator): Compound represented by the following formula (F-3), wherein “Bu” represents an n-butyl group)

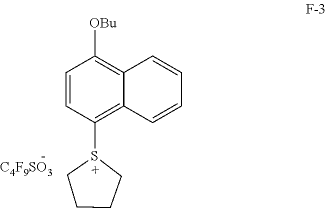

F-4 (Basic compound): Compound represented by the following formula (F-4)

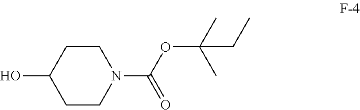

w-1 (Polymer): Polymer represented by the following formula (w-1), wherein the subscript attached beside each repeating unit is the content ratio (mol %) of the repeating unit)

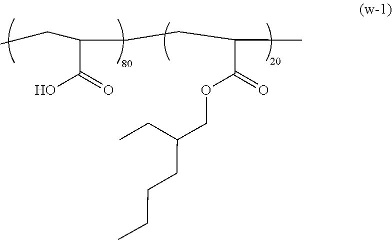

### [Synthesis Example 2-1] (Synthesis of Polymer (w-1))

63 g of acrylic acid, 36 g of 2-ethylhexyl acrylate, and 21.2 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (w-1). The Mw of the polymer (w-1) was 6,500.

### [Example 1-1] Preparation of Composition (J-1)

As shown in the following Table 2, the ingredients were mixed such that the content of (B-4) as the solvent [B] would be 99 parts by mass per 1 part by mass of the compound [A](A-1). The resulting solution was filtered through a polytetrafluoroethylene (PTFE) filter having a pore size of 0.2 μm to prepare composition (J-1). “-” for other optional components [F] in the following Table 2 indicates that the other optional components [F] were not used. The same applies hereinafter.

### [Example 1-2] Preparation of Composition (J-2)

As shown in the following Table 2, a mixture containing the compound [A](A-2) was mixed with (B-1) as the solvent [B] such that the amount of the solvent [B] would be 99 parts by mass (including the solvent [B] contained in the mixture containing the compound [A]) per 1 part by mass of the components other than the solvent in the compound [A](A-2). The resulting solution was filtered through a polytetrafluoroethylene (PTFE) filter having a pore size of 0.2 μm to prepare composition (J-2).

### [Examples 1-3 to 1-40 and Comparative Example 1-1] Preparation of Compositions (J-3) to (J-40) and (j-1)

Compositions (J-3) to (J-40) and (j-1) were prepared in the same manner as in Example 1-1 or Example 1-2 except that the type and content of each component were set as shown in the following Table 2. “-” in the following Table 2 indicates that the corresponding component was not used.

### <Evaluation>

Using the first compositions for forming an underlayer film for a metal-containing resist prepared as described above, the rectangularity of a resist pattern was evaluated by the following method. The evaluation results are shown in the following Table 2.

### <Preparation of Second Material for Forming a Metal-Containing Resist (R-1)>

### [Synthesis of Metal-Containing Compound (A)]

The compound (S-1) as the metal-containing compound (A) to be used for the preparation of the second material for forming a metal-containing resist (R-1) was synthesized by the following procedure. Into a reaction vessel, 6.5 parts by mass of isopropyltin trichloride were added while stirring 150 mL of a 0.5 N aqueous sodium hydroxide solution, and stirring was carried out for 2 hours. The precipitate formed was collected by filtration, washed twice with 50 parts by mass of water, and then dried to obtain a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

Mixed were 2 parts by mass of the compound (S-1) synthesized above and 98 parts by mass of propylene glycol monoethyl ether, and the obtained mixture was subjected to removal of residual water with activated 4 Å molecular sieve, and then filtered through a polytetrafluoroethylene (PTFE) membrane filter having a pore size of 0.2 μm. Thus, a second material for forming a metal-containing resist (R-1) was prepared.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. To the organic underlayer film was applied the first underlayer film-forming composition for a metal-containing resist prepared above, heated at 250° C. for 60 seconds, and then cooled at 23° C. for 30 seconds. Thus, an underlayer film for a metal-containing resist was formed, and the underlayer film for a metal-containing resist had an average thickness of 15 nm. The underlayer film for a metal-containing resist was coated with the second material for forming a metal-containing resist (R-1) by the spin coating method using a spin coater described above, and after a lapse of a prescribed time, heated at 90° C. for 60 seconds, and then cooled at 23° C. for 30 seconds. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 25 nm in terms of a dimension on wafer)). After the exposure, the substrate was heated at 110° C. for 60 seconds, and subsequently cooled at 23° C. for 60 seconds. Thereafter, development was performed by a paddle method using Dev-1: 2-heptanone (20 to 25° C.) or Dev-2: propylene glycol monomethyl ether acetate (20 to 25° C.) as a developer, and drying was then performed to obtain a substrate for evaluation on which a resist pattern was formed. A scanning electron microscope (“SU8220” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when a residue (defect) was present in the pattern.

TABLE 2

| | | Compound [A] or | | | | | | | |
|---|---|---|---|---|---|---|---|---|---|
| | | components | | | | | | | |
| | | other than | | | | | | | |
| | | solvent | | | | | | | |
| | | in mixture | | | | Other | | | |
| | | containing | | | | optional | | | |
| | | compound | | Solvent | | component | | | |
| | | [A]/polymer w-1 | | [B] | | [F] | | Resist pattern | Resist pattern |
| | | | Content | | Content | | Content | rectangularity | rectangularity |
| | Composition | | (parts by | | (parts by | | (parts by | Developer: | Developer: |
| | (J) | Type | mass) | Type | mass) | Type | mass) | Dev-1 | Dev-2 |
| Example 1-1 | J-1 | A-1 | 1 | B-4 | 99 | — | — | A | A |
| Example 1-2 | J-2 | A-2 | 1 | B-1 | 99 | — | — | A | A |
| Example 1-3 | J-3 | A-3 | 1 | B-1 | 99 | — | — | A | A |
| Example 1-4 | J-4 | A-4 | 1 | B-1 | 98.995 | F-1 | 0.005 | A | A |
| Example 1-5 | J-5 | A-5 | 1 | B-1 | 98.995 | F-1 | 0.005 | A | A |
| Example 1-6 | J-6 | A-6 | 1 | B-1 | 98.995 | F-1 | 0.005 | A | A |
| Example 1-7 | J-7 | A-7 | 1 | B-1 | 98.995 | F-1 | 0.005 | A | A |
| Example 1-8 | J-8 | A-7 | 1 | B-1/B-2 | 76.5/22.495 | F-1 | 0.005 | A | A |
| Example 1-9 | J-9 | A-7 | 1 | B-1/B-2 | 58.5/40.495 | F-1 | 0.005 | A | A |
| Example 1-10 | J-10 | A-7 | 1 | B-1/B-2 | 40.5/58.495 | F-1 | 0.005 | A | A |
| Example 1-11 | J-11 | A-8 | 1 | B-1 | 99 | — | — | A | A |
| Example 1-12 | J-12 | A-8 | 1 | B-1/B-5 | 76.5/22.495 | — | — | A | A |
| Example 1-13 | J-13 | A-8 | 1 | B-1/B-5 | 58.5/40.495 | — | — | A | A |
| Example 1-14 | J-14 | A-8 | 1 | B-1/B-5 | 40.5/58.495 | — | — | A | A |
| Example 1-15 | J-15 | A-9 | 1 | B-1 | 98.995 | F-1 | 0.005 | A | A |
| Example 1-16 | J-16 | A-9 | 1 | B-1/B-6 | 76.5/22.495 | F-1 | 0.005 | A | A |
| Example 1-17 | J-17 | A-9 | 1 | B-1/B-6 | 58.5/40.495 | F-1 | 0.005 | A | A |
| Example 1-18 | J-18 | A-9 | 1 | B-1/B-6 | 40.5/58.495 | F-1 | 0.005 | A | A |
| Example 1-19 | J-19 | A-10 | 1 | B-1 | 98.995 | F-1 | 0.005 | A | A |
| Example 1-20 | J-20 | A-11 | 1 | B-1 | 98.995 | F-1 | 0.005 | A | A |
| Example 1-21 | J-21 | A-11 | 1 | B-1 | 96 | F-2 | 3 | A | A |
| Example 1-22 | J-22 | A-11 | 1 | B-1 | 98.99 | F-3 | 0.01 | A | A |
| Example 1-23 | J-23 | A-11 | 1 | B-1 | 98.99 | F-4 | 0.01 | A | A |
| Example 1-24 | J-24 | A-12 | 1 | B-1 | 98.995 | F-1 | 0.005 | A | A |
| Example 1-25 | J-25 | A-13 | 1 | B-2 | 99 | — | — | A | A |
| Example 1-26 | J-26 | A-14 | 1 | B-2 | 99 | — | — | A | A |
| Example 1-27 | J-27 | A-15 | 1 | B-2 | 99 | — | — | A | A |
| Example 1-28 | J-28 | A-16 | 1 | B-2 | 99 | — | — | A | A |
| Example 1-29 | J-29 | A-17 | 1 | B-2 | 99 | — | — | A | A |
| Example 1-30 | J-30 | A-18 | 1 | B-2 | 99 | — | — | A | A |
| Example 1-31 | J-31 | A-19 | 1 | B-2 | 99 | — | — | A | A |
| Example 1-32 | J-32 | A-20 | 1 | B-2 | 99 | — | — | A | A |
| Example 1-33 | J-33 | A-21 | 1 | B-1 | 99 | — | — | A | A |
| Example 1-34 | J-34 | A-22 | 1 | B-3 | 99 | — | — | A | A |
| Example 1-35 | J-35 | A-23 | 1 | B-3 | 99 | — | — | A | A |
| Example 1-36 | J-36 | A-24 | 1 | B-2 | 99 | — | — | A | A |
| Example 1-37 | J-37 | A-25 | 1 | B-2 | 99 | — | — | A | A |
| Example 1-38 | J-38 | A-26 | 1 | B-3 | 99 | — | — | A | A |
| Example 1-39 | J-39 | A-27 | 1 | B-3 | 99 | — | — | A | A |
| Example 1-40 | J-40 | A-28 | 1 | B-2 | 99 | — | — | A | A |
| Comparative | j-1 | W-1 | 1 | B-2 | 99 | — | — | B | B |
| Example 1-1 | | | | | | | | | |

As is apparent from the results in Table 2, the underlayer films for a metal-containing resist formed from the compositions of Examples successfully imparted excellent pattern rectangularity to metal resist patterns as compared with the underlayer films for a metal-containing resist formed from the compositions of Comparative Examples.

According to the method for manufacturing a semiconductor substrate and the first underlayer film-forming composition for a metal-containing resist of the present disclosure, it is possible to form an underlayer film for a metal-containing resist capable of imparting excellent pattern rectangularity to a metal resist pattern. Therefore, these can be suitably used for the manufacture of a semiconductor substrate, and the like.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying an underlayer film-forming composition directly or indirectly to a substrate to form an underlayer film;
forming a metal-containing resist film from a metal-containing resist forming material on the underlayer film;
exposing the metal-containing resist film to extreme ultraviolet rays; and
developing the exposed metal-containing resist film,
wherein the underlayer film-forming composition comprises: a metal compound comprising at least a metal atom and an organic acid; and a solvent.

2. The method according to claim 1, wherein the metal atom is titanium, zirconium, hafnium, tantalum, tungsten, tin or a combination thereof.

3. The method according to claim 1, wherein the organic acid is a carboxylic acid.

4. The method according to claim 1, wherein the metal-containing resist forming material comprises a metal-containing compound (A) and a solvent, and a content ratio of the metal-containing compound (A) in the metal-containing resist forming material relative to components other than the solvent in the metal-containing resist forming material is 50% by mass or more.

5. The method according to claim 1, wherein
the metal-containing resist forming material comprises a metal-containing compound (B), and
the metal-containing resist film is formed by depositing the metal-containing compound (B).

6. The method according to claim 5, wherein the deposition is chemical vapor deposition or atomic layer deposition.

7. The method according to claim 1, wherein the underlayer film has a film thickness of 20 nm or less.

8. An underlayer film-forming composition comprising:
a metal compound comprising at least a metal atom and an organic acid; and
a solvent.

9. The underlayer film-forming composition according to claim 8, wherein the metal atom is titanium, zirconium, hafnium, tantalum, tungsten, tin or a combination thereof.

10. The underlayer film-forming composition according to claim 8, wherein the organic acid is a carboxylic acid.
